(19) United States
(12) Patent Application Publication
(10) Pub. No.: US 2024/0117518 A1
(43) Pub. Date: Apr. 11, 2024

(54) Method for Depositing a Bronze Alloy on a Printed Circuit and Printed Circuit Obtained by Said Method

(71) Applicant: Linxens Holding, Mantes-la-Jolie (FR)

(72) Inventors: Jerome SANSON, Mantes-la-Jolie (FR); Stephanie COQUILLARD, Mantes-la-Jolie (FR)

(21) Appl. No.: 18/267,130

(22) PCT Filed: Dec. 7, 2021
(86) PCT No.: PCT/EP2021/084523

§ 371 Date: Jun. 14, 2023

(30) Foreign Application Priority Data
Dec. 18, 2020 (FR) FR2013714

(51) Int. Cl. C25D 5/12; C25D 3/56; H05K 1/09; H05K 1/11; H05K 3/28

(52) U.S. Cl. CPC C25D 5/12; C25D 3/56; H05K 1/09; H05K 1/11; H05K 3/28; H05K 2201/032

(57) ABSTRACT

Disclosed is a method for depositing a bronze alloy on a printed circuit. Said method includes an operation of electrolytically depositing at least one layer of bronze on a copper sheet. The bronze layer includes, after deposition, 45-65% by weight of copper, 35-45% by weight of tin and 2-11% by weight of zinc. Also disclosed is a printed circuit obtained by this method.

### TECHNICAL FIELD

The invention relates to the field of printed circuits for connectors or antennas, for example, for chip card connectors and antennas or for devices intended for medical applications (for example, for detecting glucose in blood) or for connecting objects via the internet (IoT “Internet of Things”).

### PRIOR ART

For example, printed circuits according to the invention can comprise conductive tracks and/or electric contact pads etched into a sheet of electrically conductive material previously deposited onto a dielectric substrate, or even circuits comprising one or more connection gates, each made up of a sheet of electrically conductive material that is cut, then co-laminated with a dielectric substrate. Such printed circuits are used, for example, for producing contacts for electronic chip card modules, antennas for a chip card, mixed circuits comprising both contacts and an antenna, etc.

By way of an illustration, using the example of chip cards, said cards are generally made up of a rigid support, for example, made of plastic material, forming the main part of the card, in which rigid support a separately manufactured electronic module is incorporated. This electronic module comprises a printed circuit, which is generally flexible, provided with a chip (integrated circuit) and means for connecting the chip to a device allowing data in the chip to be read and/or written. These connection means, or connectors, are formed, for example, of contacts made up of conductive metal tracks flush with the electronic module, on the surface of the support. Apart from the requirement to have exceptional mechanical strength and exceptional contact corrosion resistance, as well as good electrical conduction between the chip and the contacts, on the one hand, and between the contacts and a read/write device, on the other hand, chip card manufacturers wish to match the color of the contacts to the one or more colors of the card. To this end, the contacts are generally covered either with a layer of gold, in order to obtain a golden finish, or a layer of silver or palladium, in order to obtain a silver finish. However, this type of finish raises issues. For example, palladium is a relatively expensive metal; in terms of gold, it must be deposited onto a layer of nickel, which, on the one hand, has magnetic properties that are disadvantageous for radiofrequency applications and/or for applications requiring a lack of magnetic properties, and, on the other hand, is problematic in the medical field if this must be placed in contact with or close to the skin, etc.

An aim of the invention is to produce flexible printed circuits in which palladium and/or nickel are not used or are hardly used, while retaining suitable electrical and mechanical properties for their use, notably in contact modules for a chip card.

To this end, a method for depositing a white bronze alloy onto a printed circuit is set forth hereafter. Said method notably comprises:
providing a dielectric substrate comprising a first and a second main sides, with at least one first sheet of a first electrically conductive material (for example, copper, aluminum, or one of the alloys thereof, steel, etc.) at least on the first main side;
at least one operation of electrolytically depositing at least one layer of at least one second electrically conductive material onto at least one zone of the first sheet.

Furthermore, in this method, said at least one operation of electrolytically depositing at least one layer of at least one second electrically conductive material comprises an operation of electrolytically depositing a bronze layer comprising, after deposition, 45 to 65%, advantageously 45 to 62% and preferably 45 to 50%, by weight of copper, 30 to 45%, and preferably 40 to 45%, by weight of tin, and 2 to 11%, advantageously 6 to 11%, by weight of zinc.

This method (as well as all the operations described in this document) can be implemented as “reel-to-reel”.

The bronze layer advantageously replaces a palladium layer, for example, on a visible side of a contact pad. It optionally also can avoid having to deposit nickel (while nickel is essential as a layer underlying a layer of gold, for example). The bronze layer is more economical than a palladium layer. A lack of nickel is preferable for radiofrequency applications and for some medical applications.

The aforementioned method advantageously comprises either of the following features considered independently of one another or in combination with one or more other features:
it comprises a finishing operation, during which a surface treatment is carried out after the bronze layer is deposited, in order to form, for example, a protective layer comprising an Organic Solderability Preservative (OSP) or a Self-Assembled Monolayer (SAM);
this surface treatment is carried out directly (i.e., without any other material between the protective layer and the bronze layer) on at least one portion of said bronze layer;
alternatively, if said at least one operation of electrolytically depositing at least one layer of at least one second electrically conductive material also comprises electrolytically depositing a surface layer comprising at least one element included in the list made up of gold, silver, palladium, rhodium and ruthenium, the surface treatment can be carried out directly on at least one portion of this surface layer;
said at least one operation of electrolytically depositing at least one layer of at least one second electrically conductive material also comprises electrolytically depositing, in the form of a thin layer that is less than 15 nanometers thick, at least one element included in the list made up of gold, silver and palladium;
said at least one operation of electrolytically depositing at least one layer of at least one second electrically conductive material comprises an operation of electrolytically depositing the bronze layer, as well as an operation of electrolytically depositing a nickel layer and a nickel-phosphorus layer, before the bronze layer is deposited.

According to another aspect, a printed circuit is described hereafter. It comprises contact pads configured to form contacts for at least one chip card module. This printed circuit then comprises:
on one of the main sides of the dielectric substrate, a sheet of the first electrically conductive material, at least part of the surface of which is covered with a stack of layers comprising at least a nickel layer, a nickel-phosphorus layer, and the bronze layer;

This printed circuit optionally further comprises either of the following features considered independently of one another or in combination with one or more other features:
it comprises connection wells, at the bottom of which a stack of layers is arranged comprising at least: a nickel layer, a nickel-phosphorus layer, a surface layer comprising at least one of the following elements: gold, silver, rhodium, ruthenium and palladium;
it comprises a thin layer of gold, silver or palladium, the thickness of which is less than or equal to 15 nanometers, underlying the bronze layer and the surface layer;
it comprises, on the other one of the main sides of the dielectric substrate, a second sheet of the first electrically conductive material, at least part of the surface of which is covered with a stack of layers comprising at least: a nickel layer, a nickel-phosphorus layer, a metal surface layer comprising at least one of the following elements: gold, silver, palladium, rhodium and ruthenium;
the thickness of the bronze layer is greater than or equal to 150 nanometers and less than or equal to 600 nanometers.

Further features and advantages of the invention will become apparent upon reading the detailed description and the accompanying drawings, in which:

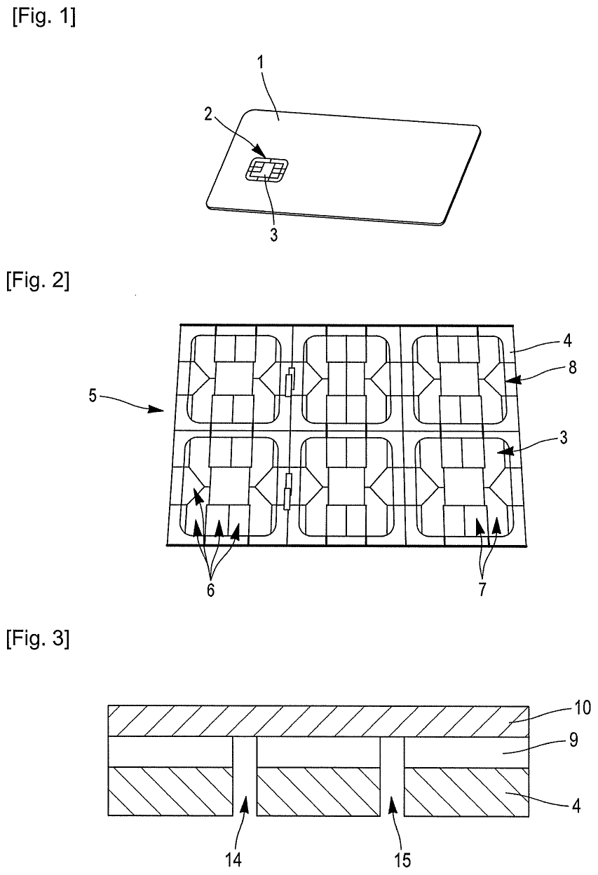

FIG. 1 schematically shows a perspective view of a chip card comprising an example of a module according to the invention;

FIG. 2 schematically shows a top view of a portion of an example of a printed circuit according to the invention, comprising several connectors for a chip card module;

FIG. 3 partially and schematically shows, as a cross-section, an example of a single-sided printed circuit for a chip card module connector such as that shown in FIG. 1;

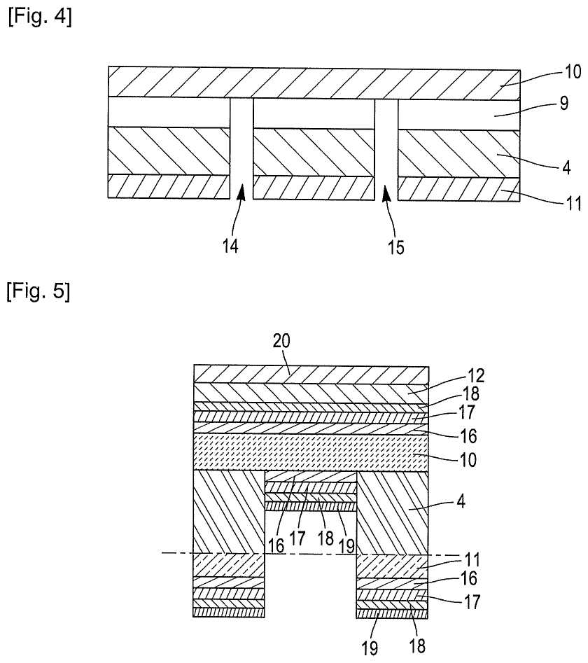

FIG. 4 partially and schematically shows, as a cross-section, an example of a double-sided printed circuit for a chip card module connector such as that shown in FIG. 1;

FIG. 5 partially and schematically shows, as a cross-section, an example of a double-sided printed circuit such as that of FIG. 4, on which several layers are electrodeposited; as well as its single-sided alternative embodiment, if the sheets and layers located under the dashed lines are removed;

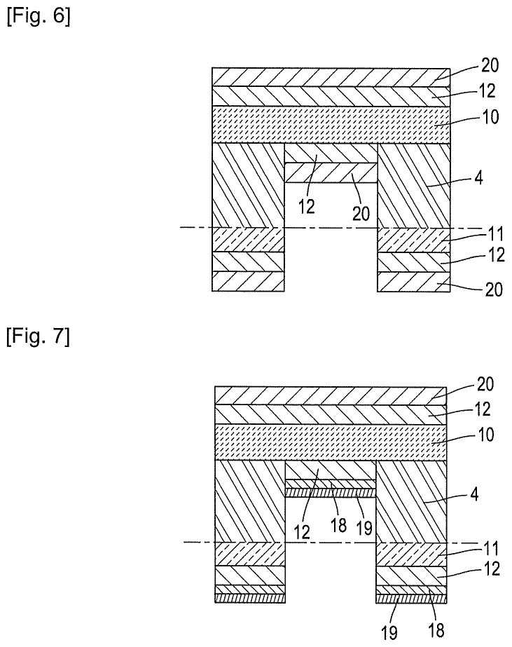

FIG. 6 partially and schematically shows, as a cross-section, another example of a double-sided printed circuit such as that of FIG. 4, on which several layers are electrodeposited; as well as its single-sided alternative embodiment, if the sheets and layers located under the dashed lines are removed;

FIG. 7 partially and schematically shows, as a cross-section, yet another example of a double-sided printed circuit such as that of FIG. 4, on which several layers are electrodeposited; as well as its single-sided alternative embodiment, if the sheets and layers located under the dashed lines are removed;

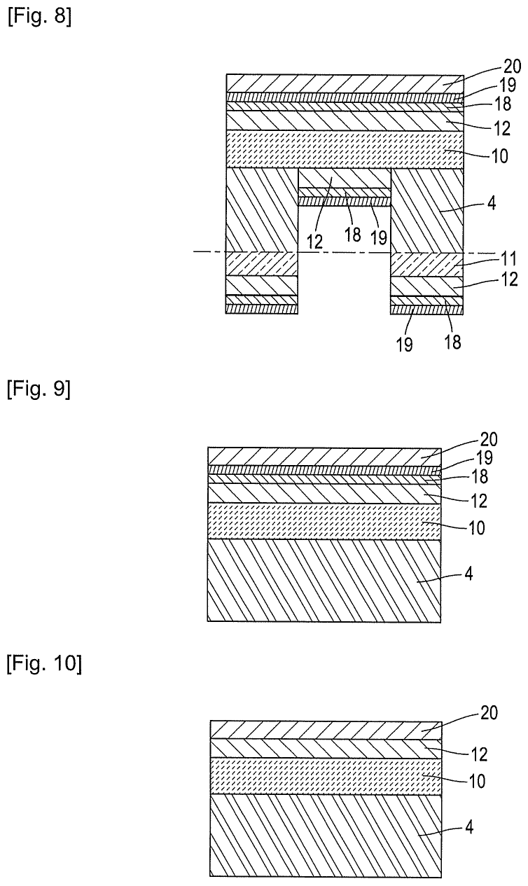

FIG. 8 partially and schematically shows, as a cross-section, yet another example of a double-sided printed circuit such as that of FIG. 4, on which several layers are electrodeposited; as well as its single-sided alternative embodiment, if the sheets and layers located under the dashed lines are removed;

FIG. 9 partially and schematically shows, as a cross-section, an example of a single-sided printed circuit such as that of FIG. 3, on which several layers are electrodeposited; and

FIG. 10 partially and schematically shows, as a cross-section, another example of a single-sided printed circuit such as that of FIG. 3, on which several layers are electrodeposited.

Throughout this document, an example of an application of the printed circuit according to the invention is taken in the field of chip cards, but a person skilled in the art will be able, without having to exercise inventive step, to transfer this example to other applications of printed circuits (contacts for a USB port, antennas, devices for medical applications, such as pressure sensors in contact with the skin, strips for detecting glucose or other compounds in blood, electrodes for carrying out an electroencephalogram, etc.).

According to an example of the application of the printed circuit according to the invention, illustrated in FIG. 1, a chip card 1 comprises a module 2 with a connector 3. According to this example, the chip card 1 is a bank card in ID-1 format. The module 2 is, for example, a bank type module (also called “EMV” (Europay Mastercard Visa)) module complying with ISO standard 7810. The module 2 is generally produced in the form of a separate element that is inserted into a cavity provided in the card. This element comprises a dielectric substrate 4 (see FIG. 2), the thickness of which ranges, for example, between 25 and 150 micrometers (therefore it is generally flexible), made of PET, polyimide, epoxy glass, etc. The connector 3 is produced on the dielectric substrate 4, to which connector a chip (not shown) is subsequently connected, via the side of the substrate opposite that comprising the connector 3.

FIG. 2 thus illustrates an example of a printed circuit portion 5, with six connectors 3. Each connector 3 comprises a range of contacts 8 made up of conductive pads 6. In the example illustrated herein, eight of the conductive pads 6 are intended to form the electric contacts 7 (denoted from C1 to C8 as defined by ISO standard 7816-2).

The connector 3 can be formed from a single-sided structure (with a sheet of conductive material on only one of the main sides of a dielectric substrate 4) or from a double-sided structure (with a sheet of conductive material on each of the two main sides of a dielectric substrate 4).

An example of single-sided structure is illustrated in FIG. 3. This single-sided structure is produced, for example, according to the following method: a dielectric substrate 4 is provided, one of the main sides of which is coated with an adhesive layer 9; then, the dielectric substrate 4 provided with the adhesive layer 9 is perforated in order to produce connection wells 14 and optionally a cavity 15, in which a chip will be subsequently housed; the dielectric substrate 4 provided with the adhesive layer 9 is then complexed (laminated) with a first sheet 10 of a first conductive material such as a copper, aluminum sheet, or an alloy thereof, or even steel, etc., before optionally undergoing hot crosslinking of the adhesive layer 9. Alternatively, a cladding can be used directly, but in this case the connection wells 14 and/or the cavity 15 are formed, for example, using a laser configured to perforate only the dielectric substrate 4. In all cases, the bottom of the connection wells 14 and/or of the cavity 15 is thus made up of an electrically conductive surface, onto which layers of conductive material optionally can be electrically deposited, with a view to an electrical connection, for example, using conductive “wire bonding” connection technology.

An example of a double-sided structure is illustrated in FIG. 4. This double-sided structure is produced, for example, according to the following method: a dielectric substrate 4 is provided that already supports, on a first one of its main sides (which will correspond to the rear side), a second sheet 11 of a first conductive material such as a copper, aluminum sheet, or one of the alloys thereof, or even steel, etc.; it is then a cladding, for example; the other one of its main sides (which will correspond to the front side) is coated with an adhesive layer 9; then this cladding provided with the adhesive layer 9 is optionally perforated in order to produce connection wells 14 and optionally a cavity 15, in which a chip will be subsequently housed; the laminate provided with the adhesive layer 9 is then complexed (laminated) with a first sheet 10 of conductive material (for example, also made of the same conductive material as the first conductive material, even if the respective thicknesses of the first 10 and second 11 sheets can be different; however, it should be noted that the first 10 and second 11 sheets can be made up of different electrically conductive materials). The bottom of the connection wells 14 and/or of the cavity 15 is thus made up of an electrically conductive surface, onto which layers of conductive material optionally can be electrodeposited, with a view to an electrical connection, for example, using conductive “wire bonding” connection technology. Alternatively, a double-sided cladding can be used directly, but in this case, the connection wells 14 and/or the cavity 15 are formed, for example, by means of a laser configured to perforate only the dielectric substrate 4 and the second sheet 11 of electrically conductive material.

For example, as shown as a cross-section in FIGS. 5 to 10, a connector 3 (i.e., basically a chipless module 2) has a multilayer structure formed by the dielectric substrate 4, an adhesive layer 9 (optional and not shown in FIGS. 5 to 10), and a first 10, and optionally a second 11, sheet made up of a first electrically conductive material, onto which at least one layer 12 of at least one second electrically conductive material is electrochemically deposited. For example, the first electrically conductive material is made up of copper or of a copper alloy. The layer 12 of second electrically conductive material is made up of bronze comprising, after deposition, 45 to 65%, advantageously to 62% and preferably 45 to 50%, by weight of copper, 30 to 45%, and preferably to 45%, by weight of tin, and 2 to 11%, advantageously 6 to 11%, by weight of zinc. The respective compositions of the bronze layer 12 are not necessarily the same on the first 10 and the second sheet 11. The composition of the bronze layer 12 deposited onto the second sheet 11 in fact can be determined by the desire to obtain better solderability thereon. The bronze layer 12 is deposited, for example, from a Miralloy® bath marketed by Umicore®, at a temperature close to or equal to 60° C., with a current density of 4 A/dm². Other materials can be electrochemically deposited between the first electrically conductive material and the bronze layer 12, or even above it.

The bronze layer 12 can be used, for example, either to replace, at least on one side, noble or precious metals (gold, silver, palladium) in a multilayer structure such as that used for producing chip card modules, or to replace, at least on one side, the nickel in a multilayer structure such as that used in devices intended for medical or radiofrequency applications, for example.

In the example illustrated in FIG. 5, the multilayer structure is a double-sided structure. It comprises a dielectric substrate 4, the nature of which has already been mentioned above. This dielectric substrate 4 is perforated, for example, in order to form connection wells 14 for electrically connecting, each one respectively, a chip located on a rear side, or “bonding side”, to contact pads 8 located on the front side, or “contact side”. This dielectric substrate 4 respectively comprises, on each of its main sides, a first 10 and a second 11 sheet, both formed by a first electrically conductive material, for example, copper or a copper alloy (alternatively, the first electrically conductive material can be aluminum, or one of the alloys thereof, steel, etc.).

Several layers of electrically conductive materials are electrochemically deposited onto at least some zones of the free surface of each of the two sheets 10, 11 of first electrically conductive material. In the example illustrated in FIG. 5, the rear side thus receives a nickel layer 16, a nickel-phosphorus layer 17, a thin layer 18 in the form of a “flash” or primer of one of the metals selected from among gold, silver and palladium, and, finally, a surface layer 19 comprising at least one of the metals selected from among gold, silver, palladium, rhodium and ruthenium. On the front side, the printed circuit successively receives a nickel layer 16, a nickel-phosphorus layer 17, a thin layer 18 in the form of a “flash” or gold primer and a bronze layer 12, the composition of which is mentioned above. Optionally, the front side undergoes a protective treatment and is therefore covered with a protective layer 20.

The table below summarizes examples of characteristic thicknesses of each of the layers of the structure illustrated in FIG. 5.

| Front side | Rear side |
|---|---|
| Adhesive 9: 10 to 25 μm | |
| Copper sheet 10: 12 to 70 | Copper sheet 11: 12 to 70 |
| micrometers | micrometers |
| Nickel layer 16: 0.5 to 6 | Nickel layer 16: 1 to 15 |
| micrometers | micrometers |
| Nickel-phosphorus layer | Nickel-phosphorus layer 17: |
| 17: 0.05 to 0.6 micrometers | 0.05-0.6 micrometers |
| Thin layer 18: Gold or Silver or | Thin layer 18: Gold or Silver or |
| Palladium: 0 to 15 nanometers | Palladium: 0 to 15 nanometers |
| Bronze layer 12: 100 | Surface layer 19 containing at |
| nanometers to 3 micrometers | least one of the elements from |
| | among: Au, Ag, Pd, Rh or Ru: 10 |
| | nanometers to 1 micrometer (up |
| | to 3 micrometers for Ag) |
| Protective layer 20 | |
| (Optional) | |

According to this example, the stack of layers on the rear side is the same whether it is at the bottom of the connection wells 14 or on the second main side of the substrate.

According to an alternative embodiment of the embodiment illustrated in FIG. 5, the rear side of the dielectric substrate 4 is left exposed (without the second sheet 11 of the first electrically conductive material and the layers (16 to 19) electrodeposited thereon); however, a stack is located at the bottom of the connection wells 14 that comprises a nickel layer 16, a nickel-phosphorus layer 17, a thin layer 18 in the form of a “flash” or primer of one of the metals selected from among gold, silver and palladium, and, finally, a surface layer 19 comprising at least one of the metals selected from among gold, silver, rhodium, ruthenium and palladium. This is then a single-sided structure.

In the example illustrated in FIG. 6, the multilayer structure is a double-sided structure. It comprises a dielectric substrate 4 as mentioned above. As in the previous example, the dielectric substrate 4 is perforated and respectively comprises, on each of its main sides, a first 10 and a second 11 sheet, both formed by a first electrically conductive material made up of, for example, as before, copper or a copper alloy. The first 10 and second 11 sheets are attached to the dielectric substrate 4 in one of the manners described above, for example.

Several layers of electrically conductive materials are electrochemically deposited onto at least some zones of the free surface of each of the two sheets 10, 11 of first electrically conductive material. In the example illustrated in FIG. 6, the front and rear sides receive a bronze layer 12. Optionally, the front and rear sides receive a protective layer 20. The protective layer 20 is optional and can be deposited onto only one of the two sides or onto the two sides. This embodiment is particularly advantageous for replacing nickel and palladium on the front side. It is also advantageous in terms of production costs because there is a limited number of electrolytic deposition operations.

The table below summarizes examples of characteristic thicknesses of each of the layers of the structure illustrated in figure

| Front side | Rear side |
|---|---|
| Adhesive 9: 10 to 25 | |
| micrometers | |
| Copper sheet 10: 12 to 70 | Copper sheet 11: 12 to 70 |
| micrometers | micrometers |
| Bronze layer 12: 100 | Bronze layer 12: 50 nanometers to 6 |
| nanometers to 3 micrometers | micrometers |
| Protective layer 20 | Protective layer 20 |
| (Optional) | (Optional) |

According to an alternative embodiment of the embodiment illustrated in FIG. 6, the rear side of the dielectric substrate 4 is left exposed and a stack is located at the bottom of the connection wells 14 that comprises the bronze layer 12 and the optional post-treatment layer 20; it is then a single-sided structure.

In the example illustrated in FIG. 7, the multilayer structure is a double-sided structure. It comprises a dielectric substrate 4 as mentioned above. As in the previous examples, the dielectric substrate 4 is perforated and respectively comprises, on each of its main sides, a first 10 and a second 11 sheet, both formed by a first electrically conductive material made up of, for example, as previously, copper or a copper alloy. The first 10 and second 11 sheets are attached to the dielectric substrate 4, in one of the manners described above, for example.

Several layers of electrically conductive materials are electrochemically deposited onto at least some zones of the free surface of each of the two sheets 10, 11 of first electrically conductive material. In the example illustrated in FIG. 7, the front and rear sides receive a bronze layer 12. Optionally, the front side receives a protective layer 20. This embodiment is particularly advantageous for replacing the nickel and the palladium on the front side. Optionally, the rear side receives, on the bronze layer 12, at least one layer comprising at least one metal from the following list: gold, silver, palladium, rhodium, ruthenium.

The table below summarizes examples of characteristic thicknesses of each of the layers of the structure illustrated in FIG. 7.

| Front side | Rear connection side |
|---|---|
| Adhesive: 10 to 25 micrometers | |
| Copper sheet 10: 12 to 70 | Copper sheet 11: 12 to 70 |
| micrometers | micrometers |
| Bronze layer 12: 100 | Bronze layer 12: 50 |
| nanometers to 3 micrometers | nanometers to 6 micrometers |
| Protective layer 20 | Thin layer 18: Gold or Silver |
| (Optional) | or Palladium: 0 to 15 |
| | nanometers |
| | (Optional) |
| | Surface layer 19 containing |
| | Au, Ag, Pd, Rh or Ru: 10 |
| | nanometers to 1 micrometer |
| | (up to 3 micrometers for Ag) |
| | (Optional) |

According to an alternative embodiment of the embodiment illustrated in FIG. 7, the rear side of the dielectric substrate is left exposed (without the second sheet 11 of the first electrically conductive material and the layers (18 to 19) electrodeposited thereon); however, a stack is located at the bottom of the connection wells that comprises a bronze layer 12, an optional thin layer 18 in the form of a “flash” or primer of one of the metals selected from among gold, silver and palladium, and, finally, at least one layer 19 comprising a metal or a compound from the following list: gold, silver, palladium, rhodium and ruthenium; this is then a single-sided structure.

In the example illustrated in FIG. 8, the multilayer structure is a double-sided structure. It differs from that described with respect to FIG. 7 basically in that, on the front side, the bronze layer 12 is covered with an optional thin layer 18 in the form of a “flash” or primer of one of the metals selected from among gold, silver and palladium, itself covered with at least one layer 19 comprising a metal from the following list: gold, silver, palladium, ruthenium, rhodium. Optionally, the front side then receives a protective layer 20.

The table below summarizes examples of characteristic thicknesses of each of the lavers of the structure illustrated in FIG. 8.

| Front side | Rear side |
|---|---|
| Adhesive: 10 to 25 micrometers | |
| Copper sheet 10: 12 to 70 | Copper sheet 11: 12 to 70 |
| micrometers | micrometers |
| Bronze layer 12: 100 nanometers | Bronze layer 12: 50 nanometers to 6 |
| to 3 micrometers | micrometers |
| Thin layer 18: Gold or Silver or | Thin layer 18: Gold or Silver or |
| Palladium: 0 to 15 nanometers | Palladium: 0 to 15 nanometers |
| (Optional) | (Optional) |
| Surface layer 19 containing Au, | Surface layer 19 containing Au, Ag, |
| Ag, Pd, Rh or Ru: 10 nanometers | Pd, Rh or Ru: 10 nanometers to 1 |
| to 1 micrometer | micrometer (up to 3 micrometers for |
| | Ag) |
| | (Optional) |
| Protective layer 20 | |
| (Optional) | |

As previously, as an alternative embodiment a single-sided structure is obtained by not covering the second main side (on the rear side) of the dielectric substrate with a second sheet 11 made up of the first conductive material and any layers deposited thereon.

In the example illustrated in FIG. 9, the multilayer structure is a single-sided structure. It comprises a dielectric substrate 4 as mentioned above. On the front side, the first sheet 10 made up of the first electrically conductive material is attached to the dielectric substrate 4 in one of the manners described above.

Several layers of electrically conductive materials are electrochemically deposited onto at least some zones of the free surface of the first sheet 10. In the example illustrated in FIG. 9, the front side receives a bronze layer 12, then optionally a thin layer 18 in the form of a “flash” or primer of one of the metals selected from among gold, silver and palladium, and, finally, at least one surface layer 19 comprising a metal from the following list: gold, silver, palladium rhodium, ruthenium. Optionally, the front side is then provided with a protective layer 20.

The table below summarizes examples of characteristic thicknesses of each of the layers of the structure illustrated in FIG. 9.

Front side

Adhesive: 10 to 25 micrometers
Copper sheet 10: 12 to 70 micrometers
Bronze layer 12: 100 nanometers to 3
micrometers
Thin layer 18: Gold or Silver or Palladium:
0 to 15 nanometers
(Optional)
Surface layer 19 containing Au, Ag, Pd,
Rh or Ru:
10 nanometers to 1 micrometer (up to 3
micrometers for Ag)
Protective layer 20
(Optional)

In the example illustrated in FIG. 10, the multilayer structure is a single-sided structure. It basically differs from that described above in that it does not comprise a thin layer 18 in the form of a “flash” or primer of one of the metals selected from among gold, silver and palladium, nor a surface layer 19 comprising a metal from the following list: gold, silver, palladium, rhodium, ruthenium.

However, optionally, the front side can then receive a protective layer 20.

The table below summarizes examples of characteristic thicknesses of each of the layers of the structure illustrated in FIG. 10.

Front side

Adhesive: 10 to 25 micrometers
Copper sheet 10: 12 to 70 micrometers
Bronze layer 12: 100 nanometers to 3
micrometers
Protective layer 20
(Optional)

In the embodiments presented above with their alternative embodiments, when a protective treatment 20 is carried out, this can correspond, in a non-exhaustive manner, to the passage through:
an organic solderability preservative bath, such as benzotriazole or an imidazole (for example, an alkyl benzimidazole, an aryl benzimidazole, etc.);
a bath suitable for forming a self-organized monolayer, such as a mixture of polyethylene glycol ether and propylene glycol, or even a mixture of octylphenoxyethanol and octadecane-1-thiol or even polyoxyethylene sorbitan monooleate (Polysorbate 80, CAS number 9005-65-6), or even a mixture of ethoxylated propoxylated alcohols (C12-18) (CAS number 69227-21-0) with lauryl polyoxyethylene) ether (CAS number 9002-92-0) and 1-octadecanethiol (CAS number 2885-00-9).

For example, a chip card module comprising a stack made up of a dielectric 4 covered with a copper sheet 10, onto which a nickel layer 16, a nickel-phosphorus layer 17, a gold flash 18 and a 0.5 micrometer bronze layer 12 comprising 45 to 50% by weight of copper, 40 to 45% by weight of tin and 6 to 11% by weight of zinc (structure of FIG. 5) are electrodeposited, has a contact resistance (CRM) of less than 500 mOhm before and after undergoing a 24 hour salt spray test, in accordance with ISO standard 10 373.

1. A method for depositing a bronze alloy on a printed circuit, comprising:
providing a dielectric substrate comprising a first and a second main sides, with at least one first sheet of a first electrically conductive material at least on the first main side;
at least one operation of electrolytically depositing at least one layer of at least one second electrically conductive material onto at least one zone of the first sheet;
characterized in that said at least one operation of electrolytically depositing at least one layer of at least one second electrically conductive material comprises an operation of electrolytically depositing a bronze layer comprising, after deposition, 45 to 65% by weight of copper, 30 to 45% by weight of tin and 2 to 11% by weight of zinc.

2. The method as claimed in claim 1, comprising a finishing operation, during which a surface treatment is carried out after the bronze layer is deposited.

3. The method as claimed in claim 2, wherein the finishing operation comprises applying a protective layer comprising an organic solderability preservative.

4. The method as claimed in claim 2, wherein the finishing operation comprises applying a protective layer comprising a self-assembled monolayer.

5. The method as claimed in claim 2, wherein the surface treatment is carried out directly on at least one portion of said bronze layer.

6. The method as claimed in claim 1, wherein said at least one operation of electrolytically depositing at least one layer of at least one second electrically conductive material also comprises electrolytically depositing a surface layer comprising at least one element included in the list made up of gold, silver, palladium, ruthenium, rhodium.

7. The method as claimed in claim 2, wherein the surface treatment is carried out directly on at least one portion of said surface layer.

8. The method as claimed in claim 6, wherein said at least one operation of electrolytically depositing at least one layer of at least one second electrically conductive material also comprises electrolytically depositing, in the form of a thin layer that is less than 15 nanometers thick, at least one element included in the list made up of gold, silver, palladium.

9. The method as claimed in claim 1, wherein said at least one operation of electrolytically depositing at least one layer of at least one second electrically conductive material comprises, before the bronze layer is deposited, an operation of electrolytically depositing a nickel layer and a nickel-phosphorus layer.

10. A printed circuit obtained by the method as claimed in claim 1, comprising contact pads configured to form contacts for at least one chip card module, said printed circuit comprising, on one of the main sides of the dielectric substrate, the first sheet of a first electrically conductive material, at least part of the surface of which is covered with a stack of layers comprising at least: a nickel layer, a nickel-phosphorus layer, the bronze layer.

11. The printed circuit as claimed in claim 10, comprising connection wells, at the bottom of which a stack of layers is arranged comprising at least: a nickel layer, a nickel-phosphorus layer, a surface layer comprising at least one of the following elements: gold, silver, rhodium, ruthenium and palladium.

12. The printed circuit as claimed in claim 11, further comprising a thin layer of gold, silver or palladium, the thickness of which is less than or equal to 15 nanometers, underlying the bronze layer and the layer.

13. The printed circuit as claimed in claim 10, comprising, on the other one of the main sides of the dielectric substrate, a second sheet (1) of a first electrically conductive material, at least part of the surface of which is covered with a stack of layers comprising at least: a nickel layer, a nickel-phosphorus layer, a surface layer comprising at least one of the following elements: gold, silver, rhodium, ruthenium and palladium.

14. The printed circuit as claimed in claim 10, wherein the thickness of the bronze layer is greater than or equal to 150 nanometers and less than or equal to 600 nanometers.
